(19) United States
(12) Patent Application Publication
(10) Pub. No.: US 2026/0190263 A1
(43) Pub. Date: Jul. 2, 2026

(54) COVER DEVICE FOR A VISUAL OUTPUT APPARATUS TO BE WORN ON THE HEAD, OUTPUT APPARATUS SET, AND METHOD

(71) Applicant: GOODLY INNOVATIONS GMBH, Grünwald (DE)

(72) Inventors: Robert HOFFMEISTER, Grünwald (DE); Jochen RAUSCHERT, Coburg (DE)

(21) Appl. No.: 18/858,227

(22) PCT Filed: Apr. 20, 2023
(86) PCT No.: PCT/EP2023/060252

§ 371 Date: Oct. 18, 2024

(30) Foreign Application Priority Data
Apr. 21, 2022 (DE) 10 2022 109 672.6

(51) Int. Cl. H05K 5/03; H05K 5/00

(52) U.S. Cl. CPC H05K 5/03; H05K 5/0086

(57) ABSTRACT

The invention relates to a cover device (10) for a visual output apparatus (20) to be worn on the head, by means of which cover device the output apparatus is partially covered and can be adjusted according to requirements depending on its particular field of application. The cover device comprises a pouch (11) and a holding frame (12) for peripherally clamping an edge strip (11_{S}) of the pouch on a modular portion (21_{B}) of the functional module (21), to be worn at the front, of the output apparatus. The invention also relates to a method for partially covering a visual output apparatus (20) to be worn on the head, and to an output apparatus set (100) comprising a visual output apparatus (20) to be worn on the head and a cover device (10) that fits the output apparatus.

The present invention relates to a cover device for a visual output apparatus to be worn on the head (i.e., designed to be worn on the head). Furthermore, the invention relates to an output apparatus set comprising a visual output apparatus to be worn on the head and a cover device, as well as to a method for partially covering a visual output apparatus to be worn on the head.

Visual output apparatuses worn to be worn on the head, also known as “head-mounted displays”, exist in a wide variety of designs and for a wide range of applications. Known output apparatuses of this type comprise a functional module which is preferably worn at the front (i.e. intended for wearing at the front) and which comprises a display device which is held in front of the eyes or at least one eye of a user when the output apparatus is used. Modified versions also position the functional modules on the side of the head and may use solely monocular displays. In addition, such output apparatuses include a head mount with which a user can fix the functional module, which is to be worn at the front, to their head. Such a head mount may, for example, comprise a band to be worn over the top of the head and/or the temple and/or at least one hoop or bracket to be worn accordingly.

In addition to the display device, the functional module to be worn at the front can in particular comprise at least partially a forehead pad, a device controller, at least one data storage device, at least one camera, at least one sensor, at least one operating element and/or at least one microphone.

At least one further functional module, which is to be worn, for example, on the back of the head, can be attached to the head mount, which can in particular comprise at least one (preferably rechargeable) battery, at least one antenna, at least part of a device electronics, at least one data storage device and/or at least one operating element.

Other versions of such output apparatuses can also be connected via a cable or via a radio connection to an external functional module, which can be worn on the belt or formed by an external computer. There are also devices that are completely voice-controlled and therefore do not require any operating elements. In special designs, a main switch can be integrated into a hinge mechanism of the output apparatus in such a way that it automatically switches the device on or off depending on the hinge position.

When used, such visual output apparatuses can limit a user's field of vision to only the artificial content displayed at any given time (e.g. as pure video glasses or as a virtual reality headset) or simply expand the user's natural view of their surroundings with additional information (e.g. as augmented reality glasses). They can be used both in the entertainment sector and in the professional field, for example to simulate, in particular to practice, certain activities, or to artificially support the performance of certain actions. By attaching it to the head, the wearer retains maximum freedom of movement and can use in particular both hands for actions, for example to influence the content displayed and/or to carry out complex work processes depending on the information displayed.

JP 2018-137626 A discloses an image generating apparatus comprising a holder which is part of a cap and which has an extended portion. Furthermore, the image generating device comprises an image display device which is attached to the extended portion. In the figures, a cap body, which is surrounded in its lower region by the ring-shaped body part, can also be seen. This device thus allows the attachment of a head-mounted display to a helmet.

US 2020/0033601 A1 describes a head-mounted display system. The user of the system preferably wears a fabric cap to which several haptic feedback actuators are attached.

A head mount for implementing a head-mounted display is known from DE 20 2021 003 714 U1. What is described is a foldable frame that can be placed on the user's head and can be shaped as desired.

The present invention is based on the object of providing a technology that allows visual output apparatuses worn on the head to be adapted to requirements dependent on their respective area of application, and thus to increase the spectrum of possible applications for these output apparatuses in a simple and convenient manner.

The object is achieved by a cover device according to claim 1, by an output apparatus set according to claim 6 and by a method according to claim 9. Advantageous embodiments are disclosed in the dependent claims, the description and the figures.

A cover device according to the invention is an additional component for a visual output apparatus to be worn on the head, which comprises a functional module which is to be worn at the front and which has a display device and—for fixing it to the head of a user-a head mount.

The cover device comprises a pouch which is designed or suitable to be pulled both over the head mount (in the form intended for use) and over a portion of the functional module, hereinafter referred to as the “modular portion”, which is spaced apart from the display device. The pouch explicitly does not have a supporting function, but rather serves to protect or encapsulate the head mount and the modular portion. This means that the pouch can be quickly removed or replaced after use, so that all other components of the output apparatus can still be used—for example if the user changes.

In addition, the cover device comprises a holding frame which is designed to clamp an edge strip of the pouch (i.e. a strip-shaped region on the edge of the pouch surrounding a pouch opening) to the modular portion spaced apart from the display device, and thus to close the pouch with the functional module while the display device remains exposed. The holding frame is removable after the clamping region has been opened later, so it can be removed from the functional module, in particular from the modular portion, without causing any damage, which thus ends the clamping and makes it possible to remove the pouch.

Preferably, the holding frame has an adaptable shape. Such a frame can be attached to and removed from the functional module to be worn at the front particularly easily. In particular, the holding frame can be detachable, i.e. can be opened and closed (repeatedly), and can then form a frame shape—i.e., surround a frame interior—only in a closed state.

An output apparatus set according to the invention comprises a visual output apparatus to be worn on the head, with a head mount and a functional module which is to be worn at the front and which comprises a display device. Furthermore, the output apparatus set comprises a cover device according to an embodiment of the present invention.

The cover device is adapted to the output apparatus—i.e., its pouch is suitable for receiving the head mount and (at the same time) at least one modular portion of the functional module spaced apart from the display device, and its holding frame is designed to clamp an edge strip of the pouch to the modular portion spaced apart from the display device and thus to close the pouch with the functional module while the display device remains exposed. To cease the clamping, the holding frame can be removed from the functional module, in particular the modular portion, without causing any damage.

In particular, the holding frame thus has a shape that is at least partially adapted to the output apparatus. As such, it can at least partially emulate an impression of the modular portion spaced apart from the display device, into which it can be inserted (preferably with a precise fit) when clamped on.

A method according to the invention serves for partially covering a visual output apparatus to be worn on the head, which itself comprises a functional module which is to be worn at the front and which has a display device and a head mount. The method comprises covering the head mount by pulling the pouch—with a cover device according to an embodiment of the present invention-over it, and also over a modular portion of the functional module to be worn at the front, said modular portion being spaced apart from the display device. According to the method, an edge strip of the pouch is then clamped to the modular portion spaced apart from the display device by means of the holding frame of the cover device, and the pouch is thus closed by the functional module (arranged in the pouch with the modular portion) while the display device remains exposed. To end the containment of the output apparatus, the holding frame of the functional module can be removed from the housing of the output apparatus, preferably without causing damage, whereby clamping can thus be ended.

The holding frame and the pouch are each preferably separate (in particular separate or separable) components. This makes it possible in particular for the pouch to be exchanged while simultaneously repeatedly using the holding frame.

The present invention thus makes it possible to cover an output apparatus worn on the head partially by means of the cover device, and at the same time to enable a user to see the display device and thus the visual information output by the output apparatus- and thereby also to continue to use the output apparatus (preferably without restrictions).

The removable holding frame allows for simple and convenient repeated use of the output apparatus, either with or without the cover device.

This allows a user to quickly and easily make the output apparatus suitable for use in a particular environmental situation. In particular, a suitable choice of pouch material can prevent, for example, penetration of moisture or particles (e.g. dust, dirt), which may originate from the head of a user or from an environment in which the output apparatus is used and could otherwise damage the output apparatus, at the output apparatus. In addition, in clean rooms, for example, it can be ensured that applicable regulatory guidelines can be complied with even when the output apparatus is in use, by preventing particles that may be present on the output apparatus from contaminating the clean room. Since the functional module, which is worn at the front, closes the pouch, the output apparatus can also be easily put on and taken off again even when partially covered in this way, while maintaining the protective effect.

The clamping is preferably carried out directly, i.e. with the pouch in contact with the modular portion and the holding frame-thus without any additional element arranged in between.

According to advantageous embodiments of the present invention, the holding frame is designed to keep one or more additional functional element(s) of the output apparatus (such as in particular at least one sensor and/or at least one camera) at least partially uncovered by the pouch, i.e. outside the pouch, when clamped on. This means that these functional elements can remain usable (preferably without restrictions) even when the output apparatus is partially covered by the cover device.

Alternatively or additionally, the holding frame may have at least one frame region with at least one opening that connects a frame interior surrounded by the holding frame with an external environment of the frame. In this way, any housing opening in the output apparatus can be covered with the pouch but kept accessible through the holding frame so that a function of the housing opening (e.g. for ventilation or as microphone or sensor access) is retained.

According to advantageous embodiments, the holding frame forms at least one receiving recess for the functional module to be worn at the front, into which the functional module is inserted for clamping the edge strip of the pouch. Such a receiving recess can advantageously define at least one position in which the functional module to be worn at the front is to be arranged relative to the holding frame when clamped. The holding frame can thus be installed particularly easily and a solid, non-slip clamping with an advantageously tight seal on the functional module arranged at the front can be achieved. In particular, in corresponding embodiments, this can make it easier to hold at least one further functional element outside the pouch during clamping as mentioned above and/or to position at least one opening, if present, in the holding frame appropriately on a housing opening in the functional module to be worn at the front.

The pouch is preferably made at least partially of a flexible, in particular fabric-, film- and/or paper-like material, for example of a fabric, a non-woven fabric (which can be formed e.g. from polyethylene filaments) and/or a film.

According to advantageous embodiments of the present invention, the pouch is at least partially waterproof and/or impermeable to inorganic dust particles and/or organic structures, for example fungal spores, bacteria or viruses. The material thickness of the pouch is preferably (at least in some areas) no more than 1 mm or no more than 0.5 mm.

Analogously, a connection between pouch and functional module created by clamping is preferably waterproof and/or impermeable to inorganic dust particles and/or organic structures, for example fungal spores, bacteria or viruses. Moisture or the respective particles and/or structures cannot then pass through the connection into or out of the pouch.

According to advantageous embodiments, together with the head mount and the modular portion of the functional module to be worn at the front, which is spaced apart from the display device, the pouch is suitable for accommodating at least one further functional module that may be additionally surrounded by the output apparatus, for example a functional module to be worn on the back of the head.

The holding frame can preferably consist at least partially of (in particular fiber-reinforced) ceramic, plastic, carbon and/or metal. Such materials are particularly durable and easy to clean. The holding frame can, for example, comprise at least one component manufactured by means of 3D printing, injection molding and/or pressing.

According to advantageous embodiments, the holding frame has at least one dimensionally stable (in particular rigid) region. This allows for particularly easy operation, and the dimensional stability also prevents the holding frame from slipping off the output apparatus.

A surface of the holding frame may comprise at least one strip to be faced towards the output apparatus during clamping, the strip width of which (as its smaller dimension) is at least 1 cm, at least 2 cm or even at least 3 cm. The strip can be designed in such a way that, when clamped on, it runs parallel to an intended viewing direction in the direction of its strip width, or extends at an angle, in particular perpendicular to the intended viewing direction; the intended viewing direction is to be understood as a direction in which a user of the output apparatus is intended to look at the display device.

Such holding frames enable a particularly durable, load-resistant and tight clamping of the edge strip of the pouch to the functional module to be worn at the front, because the pouch can be pressed against the functional module along the width of the strip.

According to advantageous embodiments, the holding frame comprises two separable (preferably at least partially rigid) frame elements. In order to close the holding frame (and thus to form the frame shape), the frame elements can be detachably connected to one another by at least one further (in particular separate) element of the holding frame. Such a further element can, for example, comprise an adjustable strap and/or consist at least partially of an elastic material (e.g. silicone and/or rubber); in particular, it can be designed as a ring. At least one of the frame elements can have at least one fixing element which is designed to fix the further element to the corresponding frame element and thus enable the connection of the frame elements. Alternatively or additionally, at least one of the frame elements can have an integrated closure device, for example a snap-in and/or locking device, by means of which the frame elements are to be connected. Upon clamping, the interconnected frame elements can contact each other or can be spaced apart.

According to another embodiment, the holding frame can comprise two (preferably at least partially rigid) wings which are pivotably connected to one another in a joint and which, in order to form the frame, must be (detachably) connected to one another at an end remote from the joint by at least one further (in particular separate) element of the holding frame and/or by a closure device integrated in at least one of the wings. Analogously to the above, the at least one further element in such embodiments can comprise an adjustable strap and/or consist at least partially of an elastic material (e.g. silicone and/or rubber). In particular, it can be designed as a ring. At least one of the wings may have at least one fixing element at its end remote from the joint, which is designed to fix the other element to the corresponding wing and thus enable the wings to be connected. The integrated closure device mentioned can—if present—comprise, for example, a snap-in and/or locking device. Upon clamping, the interconnected wings can contact each other or be spaced apart.

In particular, in these embodiments, at least one of the frame elements and/or at least one of the wings can form a receiving recess for the functional module to be worn at the front, as described above.

It goes without saying that alternative designs of the holding frame are also possible. In particular, the holding frame can be made up of one or more parts.

According to advantageous embodiments of the present invention, the holding frame has a three-dimensional profile, i.e. a structure that can be detected tactilely, on its surface that is to face the modular portion spaced apart from the display device when clamped on. Such a profile may, for example, comprise one or more studs, grooves, rails and/or beads.

In particular, such a profile can be designed to press the edge strip of the pouch against the modular portion with a distributed force during clamping. This can reduce the slippage of the pouch relative to the holding frame, thus ensuring that the pouch is particularly securely fixed to the output apparatus.

Alternatively or additionally, the holding frame may comprise one or more stabilizing structures which are designed to interact with a counter-structure on the functional module to be worn at the front, and thus to stabilize the fixation. Such an interaction can in particular comprise an engagement of the stabilizing structure in the counter-structure and/or of the counter-structure in the stabilizing structure.

According to advantageous embodiments of an output apparatus set according to the invention, the edge strip of the pouch can be clamped to the functional module to be positioned at the front in such a way that the pouch covers at least one, preferably every, region of the output apparatus that is unsuitable for wet cleaning. Accordingly, in a method according to the invention, the clamping is preferably carried out in such a way that the pouch covers at least one, preferably every, region of the output apparatus that is unsuitable for wet cleaning. In this way, depending on the material and the area of application, the pouch can prevent moisture from the surroundings from damaging the output apparatus, and/or particles or structures that cannot be removed from such areas due to the impossibility of wet cleaning there from entering the surroundings of the output apparatus set used—for example a clean room—and thus contaminating this environment.

It is also important for certain applications that parts of the output apparatus that are located inside the pouch when the output apparatus set is used can also be cleaned frequently if necessary, sometimes using aggressive cleaning agents and chemicals. The resulting separated contaminants are kept in the pouch and would not be able to contaminate the environment.

In particular, a housing element of the functional module to be worn at the front can have at least one housing opening in the modular portion spaced apart from the display device.

In such cases, the holding frame preferably has at least one frame region with at least one opening (as mentioned above), which then must be arranged—or, in the method, is arranged—at least partially on the at least one housing opening covered by a portion of the pouch wall when the edge strip of the pouch is clamped on. For example, a function of the housing opening for ventilating a functional unit of the output apparatus, or a sensor or microphone access, can be retained even when the output apparatus is partially covered by the cover device.

In the following, preferred embodiments of the invention are explained in more detail with reference to drawings. It is understood that individual elements and components can also be combined differently from how they are shown. Reference symbols for corresponding elements are used across figures and are if necessary not described again for each figure.

Schematically, in the drawings:

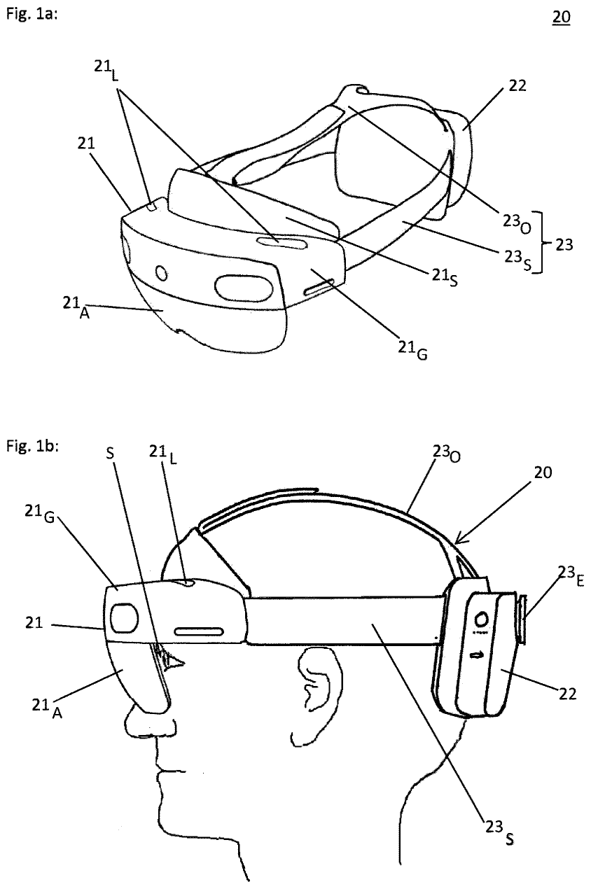

FIG. 1a: is an example of a visual output apparatus to be worn on the head, according to the prior art, in perspective view;

FIG. 1b: is the output apparatus of FIG. 1a, worn as intended on the head of a user, in a side view;

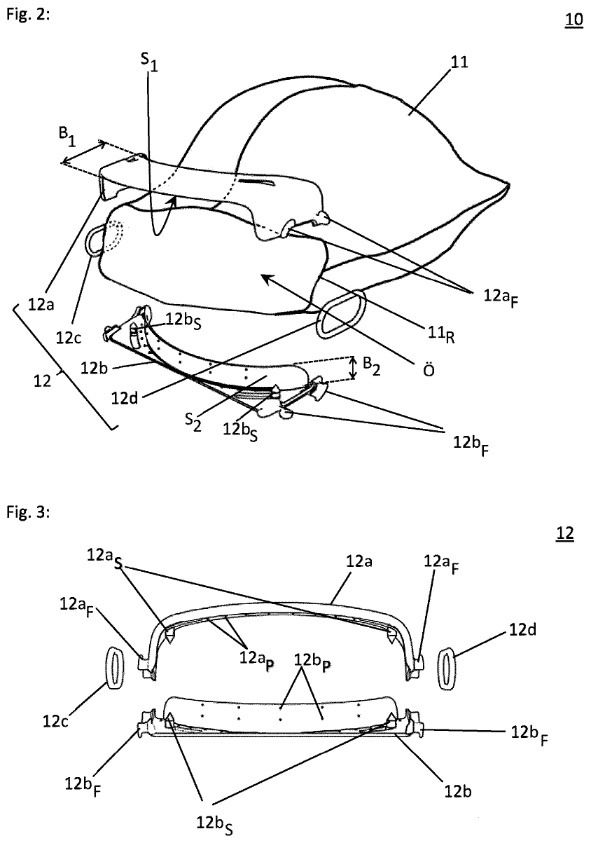

FIG. 2: is an embodiment of a cover device according to the invention,

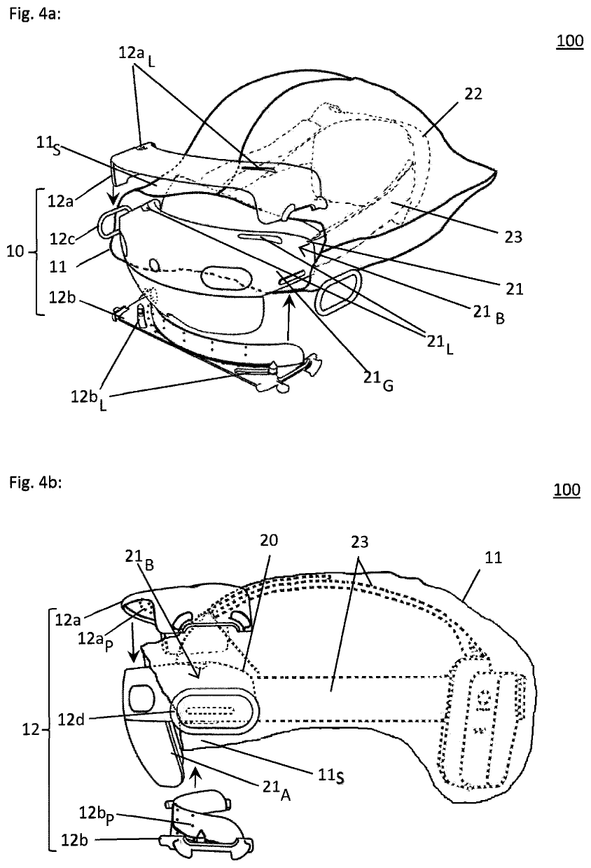

FIG. 3: is the holding frame of the cover device of FIG. 2 from a different perspective;

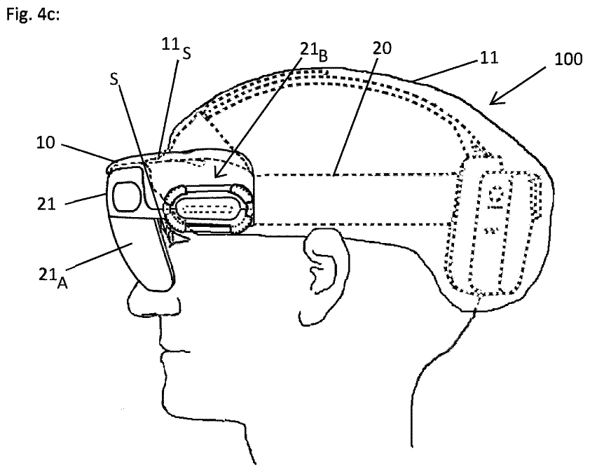

FIG. 4a: is an output apparatus set according to an embodiment of the present invention in an exploded view and/or while a method according to the invention is carried out;

FIG. 4b: is the output apparatus set of FIG. 4a in a side view in exploded view and/or while a method according to the invention is carried out; and

FIG. 4c: is the output apparatus set according to FIGS. 4a and 4b during its intended use on the head of a user.

FIGS. 1a and 1b show an example of a visual output apparatus 20 to be worn on the head. The output apparatus 20 comprises a functional module 21 to be worn at the front, with a display device 21_{A} and a forehead pad 21_{S}, a further functional module 22 to be worn on the back of the head, and a head mount 23, to which in the present case a band 23_{S} to be worn around the temple and a band to be worn over the top of the head 23_{O} belong.

As can be seen in FIG. 1b, the band 23_{S} to be worn on the temple is adjustable to a particular head size by means of an adjustment wheel 23_{E} attached to the further functional module 22, and the user looks through a designated viewing area S at the display device 21_{A}. The band 23_{O} to be worn over the top of the head forms a loop that can be adjusted to fit any head size.

The functional module 21 to be worn at the front can comprise at least part of the device electronics (in particular at least a part of a device controller, at least one data storage device, at least one camera, at least one sensor, at least one operating element and/or at least one microphone). It is at least partially enclosed by a housing element 21_{G}.

The housing element 21_{G} has housing openings 21_{L} which can be used, for example, to ventilate the components contained therein. Especially in the region of the housing openings 21_{L}, wet cleaning of the output apparatus would therefore endanger its functionality; for this reason, particles that cannot be removed, in particular organic structures (such as fungal spores, bacteria or viruses) or inorganic particles can therefore usually pass from the output apparatus (in particular through the housing openings) into an application environment and possibly contaminate it. Conversely, when the output apparatus 20 is used, for example, in damp or dusty environments, the functional module 21 can be damaged through the housing openings 21_{L}.

The same applies to the further functional module 22, which can comprise, for example, at least one (preferably rechargeable) battery, at least one antenna, at least part of the device electronics, at least one data memory and/or at least one control element (not visible in the figures) and which usually has modular portions that are not waterproof, in particular that preclude wet cleaning.

A cover device 10 according to the invention makes it possible to counteract these disadvantages. It can be designed in particular according to the embodiment shown in FIGS. 2 to 4c.

In FIG. 2, the cover device 10 is shown alone and in an exploded view. It comprises a pouch 11 which—as can be seen in FIGS. 4a to 4c—is designed (suitable) to be pulled over the further functional module 22 to be worn on the back of the head, the head mount 23, and modular portion 21_{B} of the functional module 21 which is spaced apart from the display device 21_{A} and is to be worn at the front.

The pouch 11 is preferably made at least partially of a flexible, in particular fabric-, film- and/or paper-like material. In particular, the pouch can be impermeable to organic structures such as fungal spores, bacteria and/or viruses, which may be present especially in areas of the output apparatus that cannot be cleaned wet.

As can also be seen in FIG. 2, the pouch 11 has a pouch opening Ö, which is formed by an edge 11_{R} of the pouch and is accordingly defined by the same. An edge strip 11_{S}, i.e. a strip-like region at the edge 11_{R}, is clamped to the modular portion 21_{B} of the functional module 21 which is spaced apart from the display device 21_{A} and is to be worn at the front, such that the pouch 11 is closed; this can be seen in FIGS. 4a-4c.

A holding frame 12, which is also included in the cover device 10, is used for clamping and is designed in the present case as a detachable frame with two separate, each dimensionally stable (rigid), frame elements 12a, 12b, and comprises two further elements 12c, 12d. FIG. 3 shows the frame separately and in a different perspective than FIG. 2. In FIGS. 2 and 3, the frame is shown in an exploded view, which corresponds to a detached state. In particular, the holding frame 12, when it clamps the edge strip 11_{S} onto the modular portion 21_{B}, can be removed (preferably without damage) by establishing this detached state of the functional module 21 to be worn at the front, in particular its modular portion 21_{B}, and the pouch 11 can then be removed from the output apparatus 20.

The further elements 12c, 12d each serve to connect the two frame elements 12a, 12b with each other (at corresponding ends of the frame elements). In the embodiment shown, they are designed as oval rings, which are preferably elastic (for example at least partially made of rubber and/or silicone). To connect the frame elements 12a, 12b, they are linked into fixing elements 12a_{A}, 12b_{A} formed at each end of the frame elements (12a, 12b), and thus fixed to the frame elements.

The frame element 12a in this case forms a receiving recess for the functional module 21 to be worn at the front. This determines a position of the holding frame 12 which is suitable for clamping, relative to the functional module 21 to be worn at the front, which can then be implemented easily by the user.

As shown in FIG. 2, the frame element 12a has a surface which comprises a surface strip Si of strip width B₁ which must face the modular portion 21_{B} when the edge strip 11_{S} of the pouch 11 is clamped on. The frame element 12b has a surface which comprises a surface strip S₂ of strip width B₂ which must face the modular portion 21_{B} when clamped on. In the direction of its strip width B₁, the strip S₁ in the embodiment shown runs parallel to an intended viewing direction (see FIG. 4c), and the strip S₂ runs in the direction of its strip width B2 perpendicular to the intended viewing direction. Preferably, at least one of the strip widths is at least 1 cm, at least 2 cm, or even at least 3 cm. This allows the holding frame to provide a particularly durable and tight clamping of the edge strip 11_{R} of the pouch 11 onto the functional module 21 to be worn at the front. In the illustrated embodiment, the strip widths B₁ and B₂ are different from each other, in particular in this case B₁>B₂.

As can be seen in particular from FIG. 3, the holding frame 12 has on its frame elements 12a, 12b two pin-shaped stabilizing structures 12a_{S}, 12b_{S} which are designed to interact with corresponding counter-structures on the output apparatus (not visible in the figures), namely in the present case to engage in corresponding recesses or openings in a surface of the functional module 21. The stabilizing structures serve to ensure a particularly stable, in particular slip-proof, fixation of the holding frame 12 to the functional module 21 to be worn at the front when clamped on.

Both frame elements 12a, 12b also have, on their respective surfaces which face the modular portion 21_{B} spaced apart from the display device 21_{A} when clamped on, a three-dimensional profile; due to the perspective, this can only be seen in FIG. 2 for the frame element 12b. FIGS. 3 and 4b also show the profile on the frame element 12a. The three-dimensional profile comprises a plurality of profile elements 12a_{P}, 12b_{P}, which in the embodiment shown are each designed as knobs. The profile serves to generate uneven forces at the various points during clamping, which reduces the slippage of the pouch 11 relative to the holding frame 12.

FIGS. 4a to 4c show various views of an embodiment of an output apparatus set 100 according to the invention, which comprises an output apparatus 20 and a cover device 10 according to the invention, as shown in FIGS. 1a, 1b and 2, respectively; FIG. 4c shows the output apparatus set 100 in use. For a better understanding of the arrangement, hidden components in FIGS. 4a to 4c are shown with dashed lines.

FIG. 4a, 4b illustrate how the holding frame 12, when clamping the edge strip 11_{S} of the pouch 11, engages with the modular portion 21_{B} of the functional module 21 which is to be worn at the front and which is spaced from the display device. In particular, it can be seen that the frame elements 12a, 12b of the holding frame 12 have a shape adapted to the housing element 21_{G}, and even partially emulate an impression of the functional module 21, into which it is precisely inserted when clamped.

In this case, the two openings 12a_{L} formed in the holding frame 12 are each arranged on one housing openings 21_{L} covered by the pouch 11. This allows the function of the housing openings 21_{L} (e.g. as a ventilation opening) to be retained, and the housing openings 21_{L} can still be covered by the pouch and thus secured.

The openings 12b_{L} arranged in the frame element 12b can also be arranged and/or are arranged analogously on housing openings in the housing element 21_{G} that are not visible in the figures.

In FIG. 4c, it can be seen that the pouch 11 with its edge strip 11_{S} is clamped by means of the holding frame 12 onto the modular portion 21_{B} of the functional module 21 which is to be worn on the head and which is spaced apart from the display device 21_{A}, and thus the pouch 11 is closed with the functional module 21 to be worn on the head. The display device remains exposed; in particular the intended viewing area S between the eyes of the user and the display device 21_{A} is kept uncovered by the cover device 10.

When partially covered in this way, the user can conveniently remove the output apparatus set 100 from their head, for example for interruptions in use, in particular during work breaks, and put it back on later, without losing the protective effect achieved by the cover device 10.

It is understood that the user can also wear protective clothing not shown in FIG. 4c, in particular between their head and the output apparatus 20 attached together with the cover device 10.

### LIST OF REFERENCE NUMERALS

10 cover device
11 pouch
11_{R} edge of the pouch
11_{S} edge strip of the pouch
12 holding frame
12a, 12b frame element of the holding frame
12a_{F}, 12b_{F} fixing element
12a_{S}, 12b_{S} stabilizing element
12a_{P}, 12b_{P} profile element
12a_{L}, 12b_{L} opening
12c, 12d further element of the holding frame
20 output apparatus
21 functional module to be worn at the front
21_{A} display device
21_{B} modular portion spaced from the display device
21_{G} housing element
21_{L} housing opening
21_{S} forehead pad
22 further functional module
23 head mount
23_{E} adjustment wheel
23₀ band to be worn over the top of the head
23_{S} band to be worn across the temple
100 output apparatus set
B₁, B₂ strip width:
Ö pouch opening
S intended viewing area
S₁, S₂ surface strips

1. Cover device (10) for a visual output apparatus (20) comprising a head mount (23) and a wearable functional module (21) with a display device (21_{A}), wherein the cover device comprises:
a pouch (11) for covering the head mount (23) and at least one modular portion (21_{B}) of the functional module (21) spaced apart from the display device (21_{A}); and
a holding frame (12) adapted to clamp an edge strip (11_{S}) of the pouch (11) to the modular portion (21_{B}) spaced apart from the display device (21_{A}), thereby closing the pouch with the functional module (21), while the display device (21_{A}) remains exposed.

2. Cover device according to claim 1, wherein the pouch (11) consists at least partially of a flexible material, in particular a fabric, a non-woven fabric, and/or a film.

3. Cover device according to any of claim 1 or 2, wherein the holding frame (12) comprises:
two separate frame elements (12a, 12b) which are detachably connected to one another by at least one further element (12c, 12d) of the holding frame (12) and/or by a closure device integrated in at least one of the frame elements, in order to form a frame shape of the holding frame; or
two wings which are connected in a joint so as to be pivotable relative to one another and which, in order to form a frame shape of the holding frame, are each detachably connected to one another at an end remote from the joint by at least one further element of the holding frame and/or by a closure device integrated in at least one of the wings.

4. Cover device according to any of the preceding claims, wherein the holding frame (12) has at least one opening (12a_{L}, 12b_{L}) in at least one frame region.

5. Cover device according to any of the preceding claims, wherein the holding frame (12) has a three-dimensional profile which, when clamped, faces the modular portion (21_{B}) spaced apart from the display device (21_{A}).

6. Output apparatus set (100) comprising a visual output apparatus (20) to be worn on the head, with a head mount (23) and a functional module (21_{A}) which is to be worn at the front and which comprises a display device (21), as well as a cover device (10) matching the output apparatus, according to any of the preceding claims.

7. Output apparatus set according to claim 6, wherein the pouch (11) is clamped by the holding frame (12) onto the modular portion (21_{B}) spaced apart from the display device (21_{A}) in such a manner that at least one, preferably every region of the output apparatus (20) unsuitable for wet cleaning is arranged in a pouch interior.

8. Output apparatus set according to any of claim 6 or 7, wherein a housing element (21_{G}) of the functional module (21) to be worn at the front, in the modular portion spaced apart from the display device, has at least one housing opening (21_{L}), wherein the holding frame (12) is designed according to claim 5 and wherein the at least one opening (12a_{L}, 12b_{L}) in the holding frame is arranged for clamping the edge strip of the pouch (11) onto the modular portion (21_{B}) spaced apart from the display device (21_{A}) at least partially on the at least one housing opening (21_{L}) covered by the pouch (11).

9. Method for partially covering a visual output apparatus (20) comprising a head mount (23) and a functional module (21) to be worn on the head, the same having a display device (21_{A}), the method including the following steps:
pulling a pouch (11) of a cover device (10) according to any of claims 1 to 5 over the head mount (23) and over a modular portion (21_{B}) of the functional module (21) spaced apart from the display device; and
closing the pouch, while the display device (21_{A}) remains exposed, with the functional module by clamping an edge strip (11_{S}) of the pouch (11) by means of the holding frame (12) of the cover device to the modular portion (21_{B}) spaced apart from the display device.

10. Method according to claim 9, wherein the pouch (11) is clamped by the holding frame (12) on the modular portion (21_{B}) spaced apart from the display device in such a manner that at least one, and preferably every region of the output apparatus (20) unsuitable for wet cleaning is arranged in a pouch interior of the pouch (11).
